(19) United States
(12) Patent Application Publication
(10) Pub. No.: US 2025/0055214 A1
(43) Pub. Date: Feb. 13, 2025

(54) CABLE ASSEMBLY AND CONNECTOR ASSEMBLY

(71) Applicant: SUMITOMO ELECTRIC INDUSTRIES, LTD., Osaka (JP)

(72) Inventors: Tatsuo MATSUDA, Kanuma-shi (JP); Takeshi Inoue, Osaka (JP)

(73) Assignee: SUMITOMO ELECTRIC INDUSTRIES, LTD., Osaka-shi (JP)

(21) Appl. No.: 18/791,911

(22) Filed: Aug. 1, 2024

(30) Foreign Application Priority Data
Aug. 10, 2023 (JP) 2023-130723

(51) Int. Cl. H01R 12/77; H01R 13/646

(52) U.S. Cl. CPC H01R 12/774; H01R 13/646

(57) ABSTRACT

A cable assembly includes a flat cable including a plurality of conductors arranged side by side and a covering that covers the plurality of conductors, each of the plurality of conductors having an end exposed from the covering, a ferrule including a ferrule end face and a plurality of insertion holes extending from the ferrule end face and arranged side by side, the ferrule holding the flat cable with the end of each of the plurality of conductors inserted in a corresponding one of the plurality of insertion holes, and at least one conducting member to be attached to the ferrule end face and electrically connected to end surfaces of the plurality of conductors, the end surfaces of the plurality of conductors being exposed from the ferrule end face.

### CROSS REFERENCE TO RELATED APPLICATIONS

This application claims priority based on Japanese Patent Application No. 2023-130723 filed on Aug. 10, 2023, and the entire contents of the Japanese patent application are incorporated herein by reference.

### TECHNICAL FIELD

The present disclosure relates to a cable assembly and a connector assembly.

### BACKGROUND

For example, patent literature (WO 2019/208091) discloses a connector including a flat cable and a housing that holds the flat cable.

### SUMMARY

A cable assembly according to an embodiment of the present disclosure includes a flat cable including a plurality of conductors arranged side by side and a covering that covers the plurality of conductors, each of the plurality of conductors having an end exposed from the covering; a ferrule including a ferrule end face and a plurality of insertion holes extending from the ferrule end face and arranged side by side, the ferrule holding the flat cable with the end of each of the plurality of conductors inserted in a corresponding one of the plurality of insertion holes; and at least one conducting member to be attached to the ferrule end face and electrically connected to end surfaces of the plurality of conductors, the end surfaces of the plurality of conductors being exposed from the ferrule end face. The at least one conducting member includes an elastic body elastically deformable in response to a pressing force applied to the ferrule end face, and a conducting pattern formed on an outer surface of the elastic body. The conducting pattern includes a first portion disposed on the outer surface and to be brought into contact with the end surface of a conductor included in the plurality of conductors, a second portion disposed on the outer surface at a position away from the first portion, and a third portion extending on the outer surface to connect the first portion and the second portion to each other.

### BRIEF DESCRIPTION OF THE DRAWINGS

FIG. 1 is a side view of a connector assembly according to an embodiment.

FIG. 2 is an exploded side view of the connector assembly of FIG. 1.

FIG. 3 is an exploded side view of the connector assembly as viewed from an angle different from that of FIG. 2.

FIG. 4 is a plan view of the connector of FIG. 3.

FIG. 5A is a cross-sectional view of the connector taken along line A1-A1 of FIG. 4.

FIG. 5B is a cross-sectional view of the connector taken along line A2-A2 of FIG. 4.

FIG. 5C is a cross-sectional view of the connector taken along line A3-A3 of FIG. 4.

FIG. 6A is a plan view of a conducting member of FIG. 3.

FIG. 6B is a plan view showing the conducting member as viewed from the opposite side to FIG. 6A.

FIG. 7 is a perspective view of a tube of FIG. 6A.

FIG. 8 is a cross-sectional view showing an assembly step of the connector assembly.

FIG. 9 is a cross-sectional view showing a subsequent step of FIG. 8.

FIG. 10 is a side view showing a connector assembly according to a modification.

FIG. 11 is a cross-sectional view of a connector assembly according to a comparative example.

### DETAILED DESCRIPTION

In the connector as described in the patent literature (WO 2019/208091), upper surfaces of a plurality of conductors are exposed at an end portion of the flat cable. A wiring provided in the housing is brought into contact with the upper surfaces of the conductors from above, whereby the wiring and the conductors are electrically connected to each other. However, in such a configuration, a part of a signal propagating through the conductor may be branched at a connection point between the upper surface of the conductor and the wiring and propagated to the end surface of the conductor.

In this case, transmission loss may increase due to the influence of reflection of the signal on the end surface of the conductor.

The present disclosure provides a cable assembly and a connector assembly that can reduce transmission loss.

### DESCRIPTION OF EMBODIMENTS OF PRESENT DISCLOSURE

First, the contents of embodiments of the present disclosure will be listed and explained.

(1) A cable assembly according to an embodiment of the present disclosure includes a flat cable including a plurality of conductors arranged side by side and a covering that covers the plurality of conductors, each of the plurality of conductors having an end exposed from the covering; a ferrule including a ferrule end face and a plurality of insertion holes extending from the ferrule end face and arranged side by side, the ferrule holding the flat cable with the end of each of the plurality of conductors inserted in a corresponding one of the plurality of insertion holes; and at least one conducting member to be attached to the ferrule end face and electrically connected to end surfaces of the plurality of conductors, the end surfaces of the plurality of conductors being exposed from the ferrule end face. The at least one conducting member includes an elastic body elastically deformable in response to a pressing force applied to the ferrule end face, and a conducting pattern formed on an outer surface of the elastic body. The conducting pattern includes a first portion disposed on the outer surface and to be brought into contact with the end surface of a conductor included in the plurality of conductors, a second portion disposed on the outer surface at a position away from the first portion, and a third portion extending on the outer surface to connect the first portion and the second portion to each other. The first portion, the second portion and the third portion may be integrally formed.

The cable assembly may include at least one conducting member electrically connected to the end surfaces of the plurality of conductors exposed from the ferrule end face. In this case, since the end surface of the conductor can be connected to the connection object through the conducting member, it is possible to reduce the likelihood of a part of the signal propagating through the conductor being branched in the middle of the conductor. Thus, it is possible to reduce the transmission loss due to the occurrence of signal reflection at the end surface of the conductor. Further, in the cable assembly, the conducting member includes the elastic body and the conducting pattern formed on the outer surface of the elastic body. According to this configuration, even when the end surface is formed with irregularities, the conducting pattern can be brought into contact with the end surface of the conductor more reliably by using the deformation of the elastic body when the ferrule end face is connected to the connection object. Thus, it is possible to more reliably ensure the conducting between the conductor and the conducting member. Further, in the cable assembly, the conducting pattern includes the first portion that is brought into contact with the end surface of the conductor, the second portion that is disposed on the outer surface at a position away from the first portion, and the third portion that extends on the outer surface to connect the first portion and the second portion to each other. Thus, the conductor of the flat cable can be electrically connected to the connection portion of the connection object through the conducting pattern by bringing the second portion into contact with the connection portion of the connection object. Thus, in the cable assembly, it is possible to reduce the transmission loss of a signal propagating through the conductor while ensuring electrical connection between the connection portion of the connection object and the conductor of the flat cable.

(2) In the cable assembly according to (1), the at least one conducting member may comprise a single conducting member. The single conducting member may include the elastic body and a plurality of the conducting patterns, the elastic body comprising a tube extending in an arrangement direction in which the plurality of conductors are arranged, the plurality of conducting patterns being formed on an outer surface of the tube, and the plurality of conducting patterns may be arranged on the outer surface at positions, each corresponding to one of the plurality of conductors, spaced at intervals in the arrangement direction, each of the plurality of conducting patterns being in contact with a corresponding one of the end surfaces of the plurality of conductors. In this case, as compared with the case where one conducting member is provided for each of the plurality of conductors, it is possible to reduce the occurrence of variations in stress applied to each conductor when the ferrule end face is connected to the connection object. That is, the contact pressure of each conductor is made uniform, and the contact pressure of only a specific conductor does not become large. Thus, it is possible to reduce variations in the transmission loss of the conductors due to the difference in contact pressure between the conductors.

(3) In the cable assembly according to (2), the tube may have a cylindrical shape with two ends thereof closed, and an inert liquid may be accommodated inside the tube. In this case, even if the distance between each conductor and each connection portion of the connection object is slightly different when the conductor is electrically connected to the connection object through the conducting member, the force of the tube pressing each conductor and each connection portion is uniform according to Pascal's law. Thus, the variation of the transmission loss of each conductor caused by the difference of the contact pressure of each conductor is reduced.

(4) In the cable assembly according to (3), the tube may include a pair of lids placed at the two ends to close the two ends, and the pair of lids may be made of a harder material than the tube. In this case, the elastic force of the tube acts in a direction in which each conducting pattern and each conductor or each connection portion of the connection object are brought into contact with each other. Thus, it is possible to more reliably ensure the conducting between the flat cable and the conducting member.

(5) In the cable assembly according to any one of (2) to (4), each of the plurality of conducting patterns may have an annular shape extending along the outer surface so as to be wrapped around a central axis of the tube. In this case, each conducting pattern can be easily brought into contact with the end surface of each conductor.

(6) In the cable assembly according to any one of (2) to (5), the single conducting member may further include a plate-shaped frame body into which the tube is to be fitted. The frame body may include a front surface having therein a first opening from which the first portions of the plurality of conducting patterns are exposed and a rear surface having therein a second opening from which the second portions of the plurality of conducting patterns are exposed, and the front surface may be attached to the ferrule end face. In this case, the tube can be easily attached to the ferrule end face through the plate-shaped frame body.

(7) In the cable assembly according to any one of (1) to (6), the ferrule may further include a ferrule side face extending from the ferrule end face in an extending direction in which the plurality of conductors extend, and the ferrule side face may have an engaging portion engageable with a connection object. In this case, the ferule and the connection object can be positioned by using the engaging portion. Thus, it is possible to more reliably bring the conducting pattern into contact with the end surface of the conductor when the ferrule end face is connected to the connection object. Thus, it is possible to more reliably ensure the conducting between the flat cable and the conducting member.

(8) In the cable assembly according to any one of (1) to (7), the ferrule end face may have a recess, the recess being recessed rom ferrule end face toward a side opposite to the at least one conducting member, and the recess may be configured such that at least a portion of the elastic body is receivable in the recess. In this case, the contact area of the conducting member with respect to the ferrule can be increased as compared with the case where the ferrule end face is a flat surface. Thus, it is possible to more reliably attach the conducting member to the ferrule by using the recess.

(9) In the cable assembly according to any one of (1) to (8), each of the end surfaces of the plurality of conductors may have a circular shape when viewed along an extending direction in which the plurality of conductors extend. In this case, the conducting pattern can be easily brought into contact with the end surface of the conductor.

(10) A connector assembly according to an embodiment of the present disclosure includes a flat cable including a plurality of conductors arranged side by side and a covering that covers the plurality of conductors, each of the plurality of conductors having an end exposed from the covering; a ferrule including a ferrule end face and a plurality of insertion holes extending from the ferrule end face and arranged side by side, the ferrule holding the flat cable with the end of each of the plurality of conductors inserted in a corresponding one of the plurality of insertion holes; a connection object including a plurality of connection portions, each facing a corresponding one of end surfaces of the plurality of conductors, the connection object facing the ferrule end face; and at least one conducting member disposed between the ferrule end face and the connection object and configured to electrically connect each of the end surfaces of the plurality of conductors to a corresponding one of the plurality of connection portions, the end surfaces of the plurality of conductors being exposed from the ferrule end face. The at least one conducting member includes an elastic body elastically deformable in response to a pressing force applied to the ferrule end face, and a conducting pattern formed on an outer surface of the elastic body. The conducting pattern includes a first portion disposed on the outer surface and to be brought into contact with the end surface of a conductor included in the plurality of conductors, a second portion disposed on the outer surface at a position away from the first portion, the second portion being brought into contact with a connection portion included in the plurality of connection portions, and a third portion extending on the outer surface to connect the first portion and the second portion to each other.

The connector assembly is configured to connect the cable assembly to the connection object, and the effects thereof are the same as described above.

### Details of Embodiments of Present Disclosure

Specific examples of the cable assembly and the connector assembly of the present disclosure will be described below with reference to the drawings. The present disclosure is not limited to these examples, but is defined by the scope of the claims, and is intended to include all modifications within the meaning and scope equivalent to the scope of the claims. In the description of the drawings, the same elements are denoted by the same reference numerals, and redundant description will be omitted.

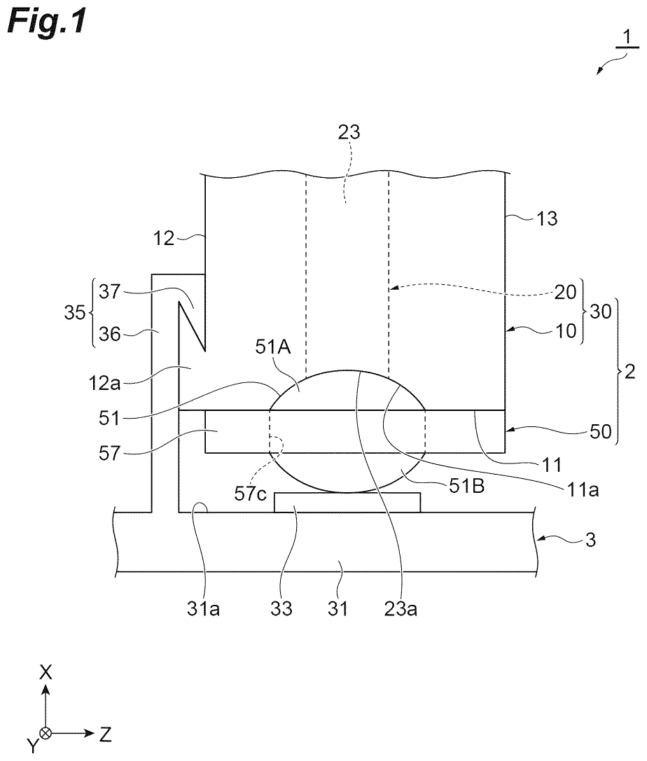

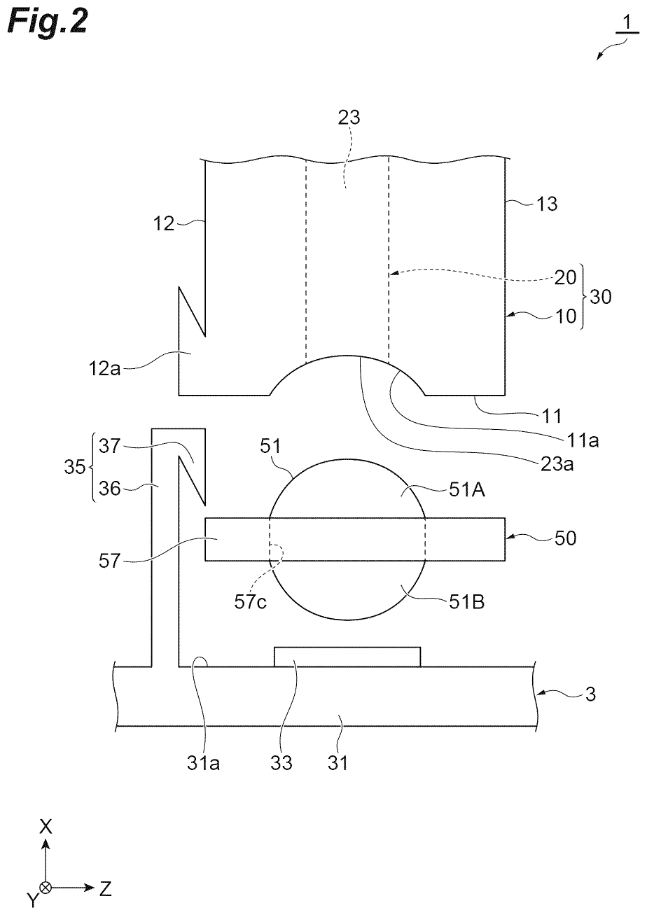

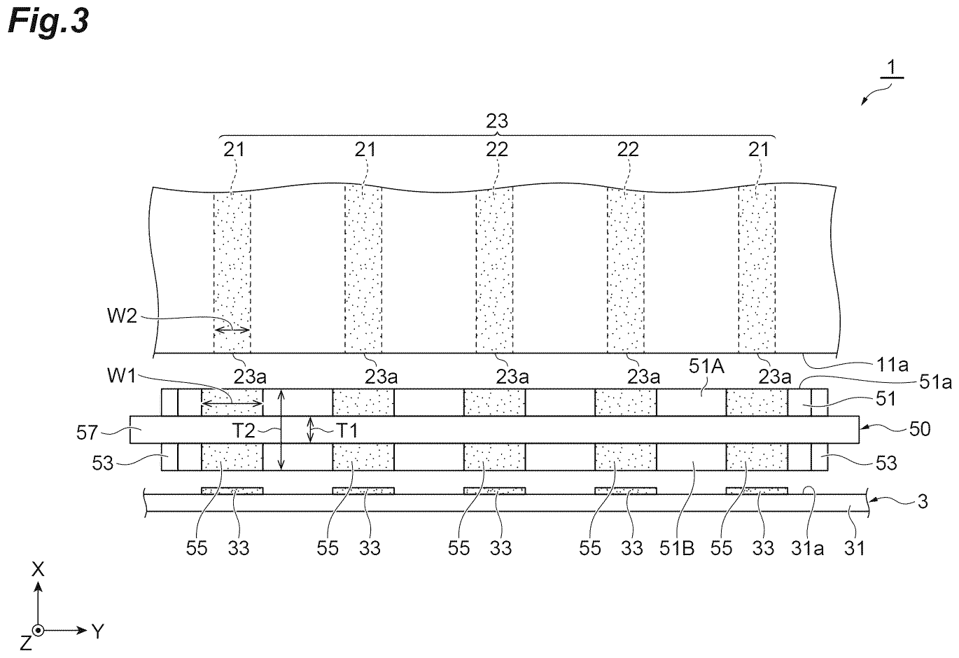

FIG. 1 is a side view of a connector assembly 1 according to an embodiment. FIG. 2 is an exploded side view of connector assembly 1. FIG. 3 is an exploded side view of connector assembly 1 as viewed from an angle different from that of FIG. 2. As shown in FIGS. 1 to 3, connector assembly 1 includes, for example, a cable assembly 2 and a connection board 3 (an example of a “connection object”). In each of the drawings, for convenience, an XYZ orthogonal coordinate system is shown in which a connection direction of cable assembly 2 with respect to connection board 3 is set as the X-axis direction.

Cable assembly 2 includes, for example, a connector 30 and a conducting member 50. Connector 30 includes, for example, a ferrule 10 and a flat cable 20. Flat cable 20 is, for example, a flexible flat cable (FFC). Ferrule 10 holds an end of flat cable 20 extending along the X-axis direction.

Ferrule 10 includes, for example, a ferrule end face 11, a ferrule side face 12, and a ferrule side face 13. Ferrule end face 11 is a surface intersecting the X-axis direction and is located at the tip of ferrule 10 in the X-axis direction. Each of ferrule side faces 12, 13 is a face intersecting with the Z-axis direction perpendicular to the X-axis direction, and is arranged along the Z-axis direction. Ferrule side faces 12, 13 extend from ferrule end face 11 along the X-axis direction.

As shown in FIGS. 1 and 2, a recess 11a is formed in ferrule end face 11. Recessed portion 11a is formed in a central portion of ferrule end face 11 in the Z-axis direction, and extends linearly along the Y-axis direction perpendicular to the X-axis direction. When a plurality of conductors 23 described later are arranged in a row, recess 11a is formed in the central portion of ferrule end face 11 in the Z-axis direction. On the other hand, when the plurality of conductors 23 are arranged in two or more rows, recess 11a is formed at a position shifted from the central portion. In the cross section of ferrule 10 along the XZ plane perpendicular to the Y-axis direction, for example, recess 11a has a curved shape recessed from ferrule end face 11 toward the side opposite to conducting member 50. An upper portion 51A of a tube 51, which will be described later, is accommodated in recess 11a. Ferrule side face 12 is formed with an engaging portion 12a for engaging with an engaged portion 37 described later.

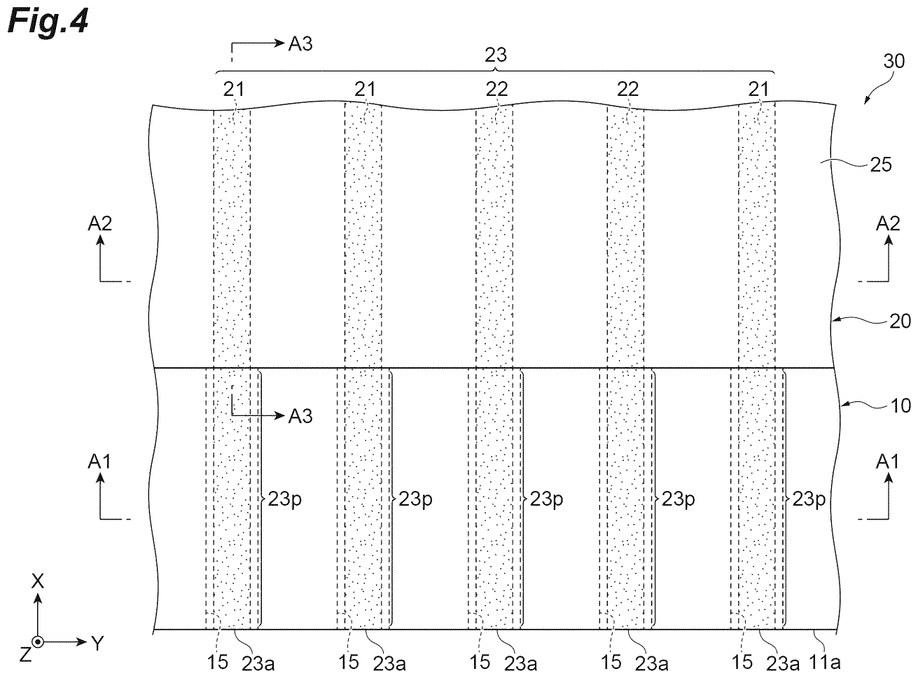

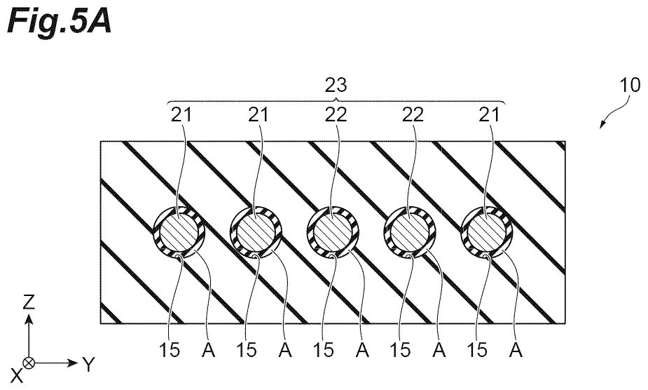

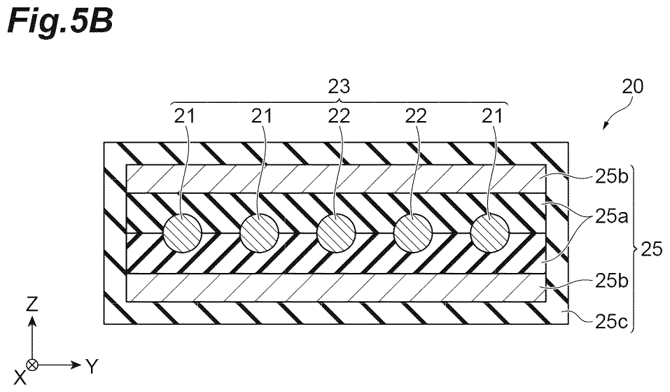

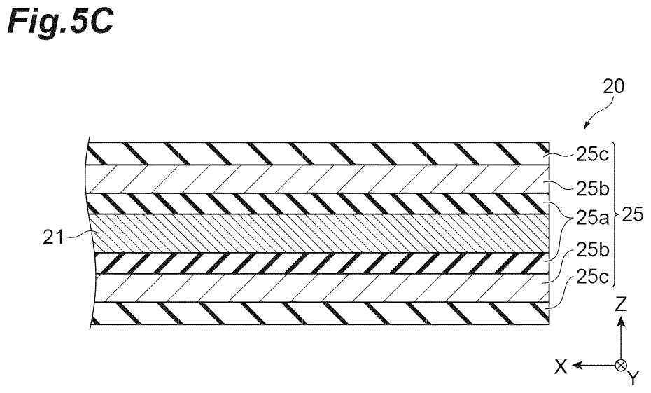

FIG. 4 is a plan view of connector 30. FIG. 5A is a cross-sectional view of connector 30 taken along the line A1-A1 of FIG. 4. FIG. 5B is a cross-sectional view of connector 30 taken along the line A2-A2 of FIG. 4. FIG. 5C is a cross-sectional view of connector 30 taken along the line A3-A3 of FIG. 4. As shown in FIGS. 4 and 5A, ferrule 10 further includes a plurality of insertion holes 15. Insertion holes 15 are arranged at intervals along the Y-axis direction. Each insertion hole 15 is opened in ferrule end face 11. As shown in FIG. 5A, each insertion hole 15 has, for example, a circular shape in the cross section of ferrule 10 along the YZ plane perpendicular to the X-axis direction.

As shown in FIGS. 5B and 5C, flat cable 20 includes a plurality of conductors 23 and a covering 25. The plurality of conductors 23 is arranged at intervals along the Y-axis direction and extends along the X-axis direction. Thus, in the embodiment, the X-axis direction may be an example of an extending direction in which each conductor 23 extends, and the Y-axis direction may be an example of an arrangement direction in which conductors 23 are arranged. In each drawing, for convenience, each conductor 23 is hatched with a dot pattern. The plurality of conductors 23 includes a plurality of first conductors 21 functioning as working electrodes and a plurality of second conductors 22 functioning as ground electrodes. For example, two first conductors 21 adjacent to each other and two second conductors 22 adjacent to each other are alternately arranged along the Y-axis direction.

Covering 25 covers each conductor 23. Covering 25 functions as an insulating layer that ensures electrical insulation between conductors 23. An end 23p of each conductor 23 is inserted into each insertion hole 15 in a state of being exposed from covering 25 (see FIG. 4). An end surface 23a of each conductor 23 reaches recess 11a formed in ferrule end face 11 and is exposed from recess 11a of ferrule end face 11. End surface 23a of each conductor 23 has, for example, a circular shape when viewed in the X-axis direction. Covering 25 as well as each conductor 23 may be covered with ferrule 10. In this case, ferrule 10 is formed with a plurality of round holes (corresponding to the above-described “plurality of insertion holes 15”) through which the plurality of conductors 23 are respectively passed, and one wide hole through which covering 25 (the insulating film portion of flat cable 20) is passed.

Covering 25 includes, for example, an insulating layer 25a, a shield layer 25b, and a protection layer 25c. Insulating layer 25a is formed of, for example, a two layer film. Each conductor 23 is arranged between two films of insulating layer 25a. Insulating layer 25a may be formed by extruding a resin around the plurality of conductors 23. Shield layer 25b is formed of two metal shield layers sandwiching insulating layer 25a from above and below. As shield layer 25b, for example, a metal (for example, copper or aluminum) foil having a thickness of 5 μm to 20 μm can be used. Protection layer 25c is arranged so as to sandwich shield layer 25b from above and below. As shown in FIG. 5C, from the viewpoint of preventing the end of shield layer 25b in the width direction from being exposed, protection layer 25c is preferably wound so as to surround shield layer 25b. Each of the layers constituting covering 25 is preferably bonded to each other by an adhesive. Shield layer 25b is connected to a ground circuit of a connection partner through, for example, a ground line or a shell.

As shown in FIGS. 1 to 3, conducting member 50 is disposed between connector 30 and connection board 3 in the X-axis direction. Conducting member 50 is attached to ferrule end face 11. Conducting member 50 is electrically connected to both connector 30 and connection board 3. Thus, connector 30 is electrically connected to connection board 3 through conducting member 50.

Connection board 3 includes, for example, a board main body 31, a plurality of connection pads 33 (an example of “connection portion”), and an engaging member 35. The plurality of connection pads 33 are arranged on a main surface 31a of board main body 31. As shown in FIG. 3, each of connection pads 33 is arranged at intervals along the Y-axis direction on main surface 31a. Each connection pad 33 is disposed at a position facing end surface 23a of each conductor 23 of connector 30 in the X-axis direction. Each connection pad 33 is electrically connected to end surface 23a of each conductor 23 through conducting member 50.

As shown in FIGS. 1 and 2, engaging member 35 includes, for example, a protruding portion 36 protruding from main surface 31a of board main body 31 in the X-axis direction, and engaged portion 37 formed at the tip of protruding portion 36. Engaged portion 37 engages with engaging portion 12a formed in ferrule side face 12 in the X-axis direction. In a state where engaging portion 12a is engaged with engaged portion 37 in the X-axis direction, the position of ferrule 10 in the X-axis direction with respect to connection board 3 is fixed. For example, when engaging portion 12a is a recess, engaged portion 37 may be a protrusion that enters the recess. For example, when engaging portion 12a is a protrusion, engaged portion 37 may be a recess that is fitted into the protrusion.

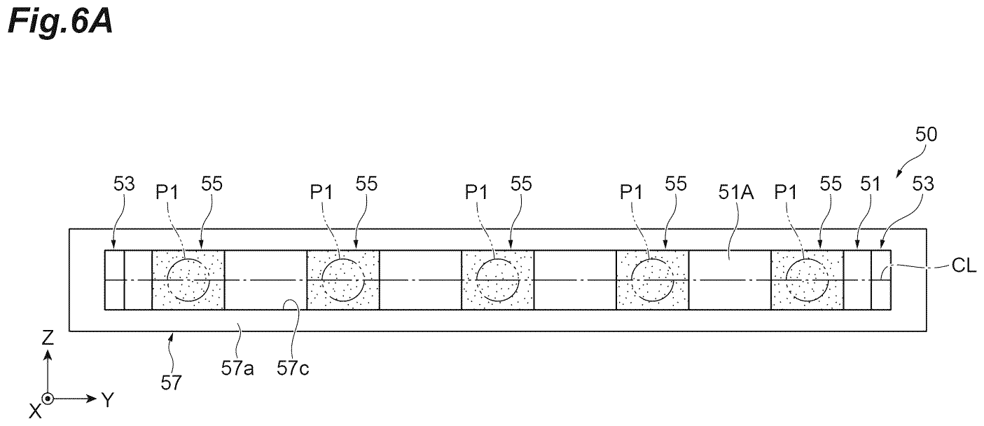

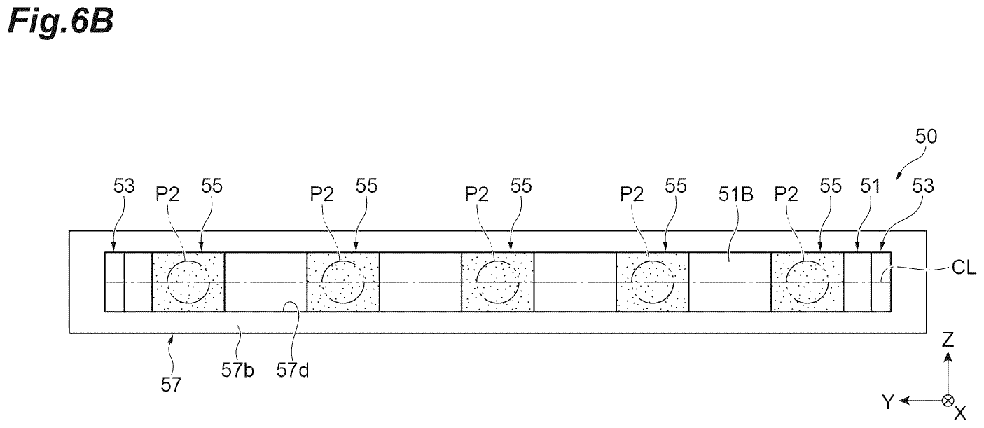

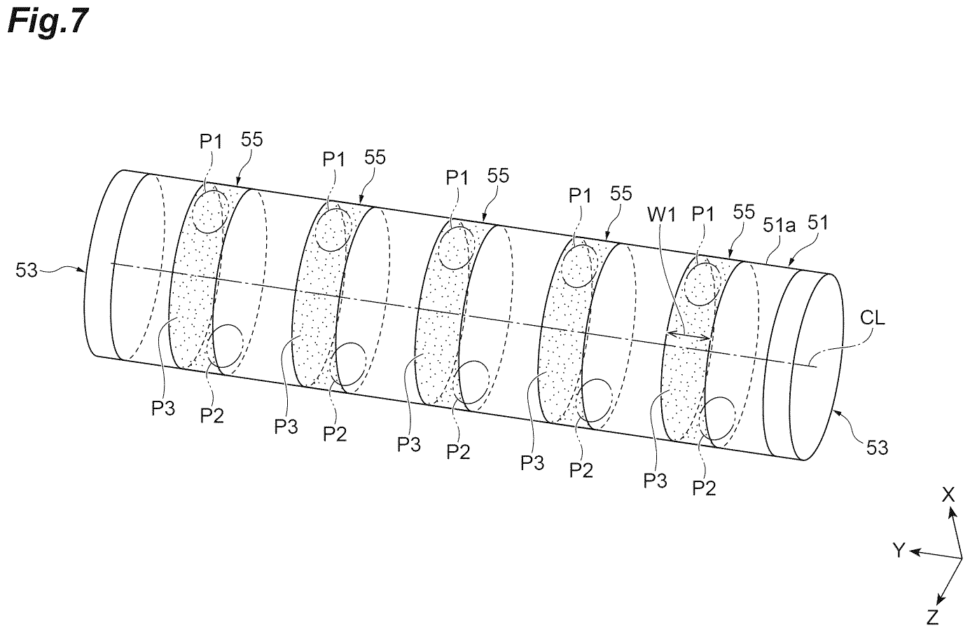

FIG. 6A is a plan view of conducting member 50. FIG. 6B is a plan view of conducting member 50 as viewed from the opposite side to FIG. 6A. FIG. 7 is a perspective view of tube 51 provided in conducting member 50. As shown in FIGS. 6A, 6B, and 7, conducting member 50 includes, for example, tube 51 (an example of an “elastic body”), a pair of lids 53, a plurality of conducting patterns 55, and a frame body 57.

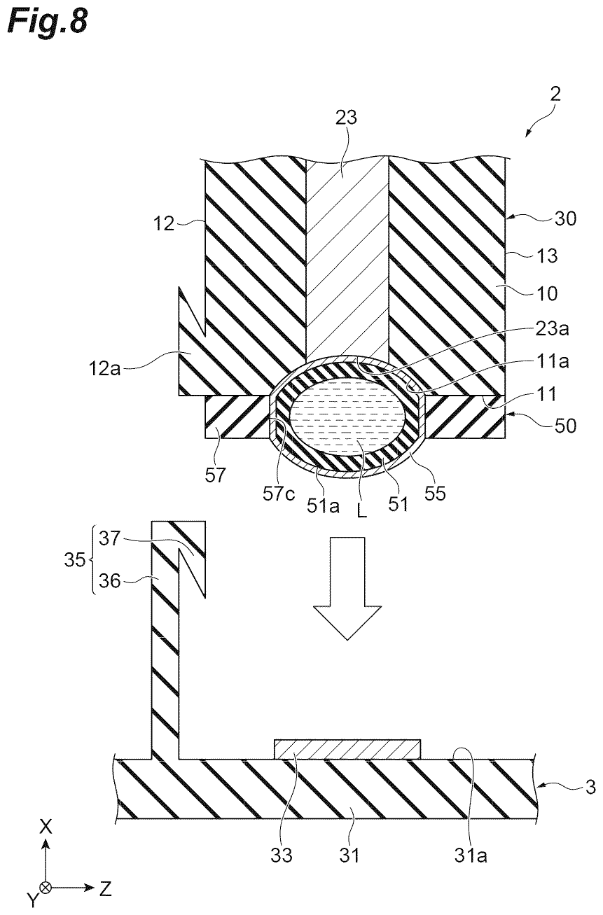

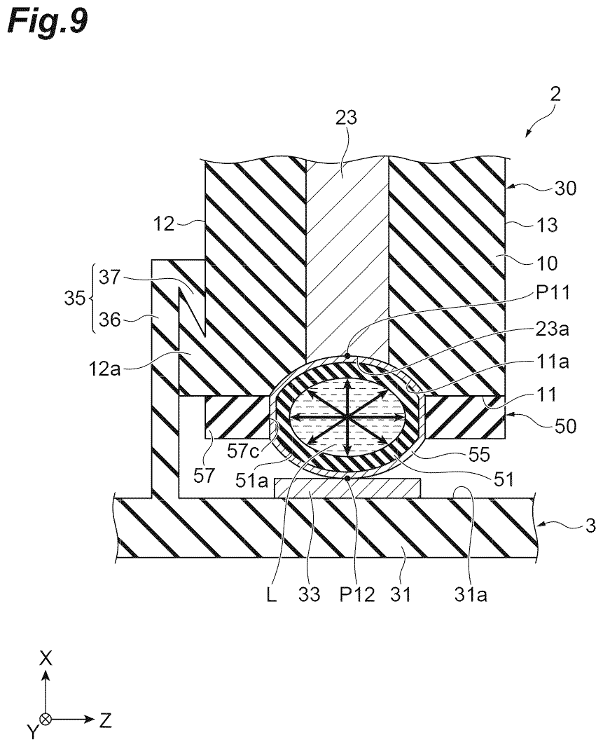

Tube 51 is, for example, an elastic member having a cylindrical shape extending along the Y-axis direction. Tube 51 is formed of, for example, an elastic body such as rubber or elastic resin. Tube 51 has, for example, a cylindrical shape with a central axis CL of tube 51 along the Y-axis direction as the center. Two ends of tube 51 along the Y-axis direction are opened, and an inert liquid L (see FIGS. 8 and 9 described later) is accommodated in tube 51. Inert liquid L may be filled in tube 51. Inert liquid L may be, for example, a fluorine-based inert liquid which is an organic solution containing fluorine. The fluorine-based inert liquid has high electrical insulation properties.

The two ends of tube 51 are closed by a pair of lids 53. Each lid 53 may be, for example, a disc-shaped member. Each lid 53 is made of a material harder than tube 51. In other words, each lid 53 has a higher Young's modulus than tube 51. The material of each lid 53 may be, for example, a metal or a resin. Each lid 53 may be composed of, for example, a non-elastic body (rigid body) having no elasticity, instead of a deformable elastic body.

The plurality of conducting patterns 55 are formed on an outer circumferential surface 51a (an example of an “outer surface”) of tube 51. Each of conducting patterns 55 is a wiring pattern having conductivity. Each of conducting patterns 55 may have elasticity so as to be able to expand and contract in accordance with elastic deformation of tube 51. As shown in FIG. 3, each of conducting patterns 55 is arranged at intervals along the Y-axis direction on outer circumferential surface 51a so as to correspond to the arrangement of each of conductors 23 of flat cable 20. Each of conducting patterns 55 faces end surface 23a of each of conductors 23 in the X-axis direction. Each of conducting patterns 55 is in contact with end surface 23a of each of conductors 23 and is electrically connected to end surface 23a of each of conductors 23. Further, each of conducting patterns 55 faces each of connection pads 33 in the X-axis direction. Each of conducting patterns 55 is in contact with each of connection pads 33 and is electrically connected to each of connection pads 33.

As shown in FIG. 7, conducting pattern 55 has, for example, an annular shape with central axis CL as the center. Conducting pattern 55 extends, for example, so as to be wrapped around central axis CL on outer circumferential surface 51a. A width W1 of conducting pattern 55 in the Y-axis direction may be constant at each position along outer circumferential surface 51a. Width W1 of conducting pattern 55 in the Y-axis direction may be larger than, for example, a width W2 of conductor 23 in the Y-axis direction (see FIG. 3). Conducting pattern 55 includes at least a conductor contact portion P1 (an example of a “first portion”) that contacts end surface 23a of conductor 23, a pad contact portion P2 (an example of a “second portion”) that contacts connection pad 33, and an intermediate portion P3 (an example of a “third portion”) that connects conductor contact portion P1 and pad contact portion P2. In FIG. 7, conductor contact portion P1 and pad contact portion P2 are shown by a two dot chain line.

Pad contact portion P2 is disposed at a position separated from conductor contact portion P1 on outer circumferential surface 51a in the X-axis direction. For example, pad contact portion P2 may be disposed on outer circumferential surface 51a at a side opposite to conductor contact portion P1. That is, pad contact portion P2 is arranged at a position facing conductor contact portion P1 in the X-axis direction with central axis CL interposed therebetween. Intermediate portion P3 extends so as to connect conductor contact portion P1 and pad contact portion P2 on outer circumferential surface 51a. Thus, conductor 23 is electrically connected to connection pad 33 through conductor contact portion P1, intermediate portion P3, and pad contact portion P2. Conducting pattern 55 does not necessarily have an annular shape as long as it includes conductor contact portion P1, pad contact portion P2, and intermediate portion P3, and may have a shape in which a part of an annular ring is cut off, such as a semicircular arc shape.

Frame body 57 shown in FIGS. 6A and 6B is, for example, a plate-shaped member having a rectangular outer shape when viewed along the X-axis direction. Frame body 57 includes a front surface 57a facing ferrule end face 11 and a rear surface 57b facing connection board 3. A first opening 57c formed in front surface 57a has a rectangular shape slightly smaller than the outer shape of frame body 57 when viewed from the X-axis direction. Similarly, a second opening 57d formed in rear surface 57b has a rectangular shape slightly smaller than the outer shape of frame body 57 when viewed along the X-axis direction. Tube 51 is fitted into frame body 57 by, for example, press-fitting.

As shown in FIG. 3, a width T1 of frame body 57 in the X-axis direction is smaller than a width T2 of tube 51 in the X-axis direction. Width T1 of frame body 57 may be, for example, less than or equal to half of width T2 of tube 51. In a state where tube 51 is fitted into frame body 57, upper portion 51A of tube 51 protrudes from first opening 57c of frame body 57, and a lower portion 51B of tube 51 protrudes from second opening 57d of frame body 57. Upper portion 51A may be a portion of tube 51 located on one side of central axis CL in the X-axis direction. Lower portion 51B of tube 51 may be the other portion of tube 51 located on the other side with central axis CL interposed therebetween in the X-axis direction. Upper portion 51A of tube 51 protruding from first opening 57c is accommodated in recess 11a (see FIG. 1) of ferrule end face 11. Upper portion 51A of tube 51 being accommodated in recess 11a means that at least a portion of upper portion 51A of tube 51 is disposed in an inner region of recess 11a.

As shown in FIG. 6A, in a state where tube 51 is fitted into frame body 57, conductor contact portion P1 of conducting pattern 55 formed in upper portion 51A of tube 51 is exposed from first opening 57c. Thus, conductor contact portion P1 is disposed at a position protruding from first opening 57c toward recess 11a in the X-axis direction. On the other hand, as shown in FIG. 6B, pad contact portion P2 of conducting pattern 55 formed in lower portion 51B of tube 51 is exposed from second opening 57d. Thus, pad contact portion P2 is disposed at a position protruding in the X-axis direction from second opening 57d toward connection pad 33.

As shown in FIG. 1, front surface 57a of frame body 57 is fixed to ferrule end face 11. The method of fixing frame body 57 to ferrule 10 is not particularly limited. For example, front surface 57a of frame body 57 may be fixed to ferrule end face 11 by adhesion or welding, or may be fixed to ferrule end face 11 by another method. Upper portion 51A of tube 51 may be fixed to recess 11a.

FIG. 8 is a cross-sectional view showing the assembly step of connector assembly 1 described above. FIG. 9 is a cross-sectional view showing a subsequent step of FIG. 8. When connector assembly 1 is assembled, cable assembly 2 is obtained by first attaching conducting member 50 to ferrule end face 11. In this state, end surface 23a of each conductor 23 held by ferrule 10 is in contact with each conducting pattern 55 of conducting member 50, and each conductor 23 and each conducting pattern 55 are conducting. When cable assembly 2 is connected to connection board 3, as shown in FIG. 8, cable assembly 2 is brought close to connection board 3 in a state where ferrule end face 11 is opposed to main surface 31a of connection board 3 in the X-axis direction through conducting member 50, and engaging portion 12a of ferrule 10 is engaged with engaged portion 37 of connection board 3 in the X-axis direction. Thus, the position of cable assembly 2 with respect to connection board 3 is determined.

At this time, as shown in FIG. 9, each conducting pattern 55 of conducting member 50 is brought into contact with each connection pad 33, and conducting member 50 receives a reaction force from each connection pad 33. Tube 51 of conducting member 50 receives the reaction force from each connection pad 33 as a pressing force to ferrule end face 11 and is elastically deformed in the X-axis direction. As a result, tube 51 contracts in the X-axis direction, and each conducting pattern 55 is in contact with each connection pad 33. Here, when tube 51 is filled with inert liquid L as in the embodiment, the pressure generated at one point by the deformation of tube 51 is transmitted to all portions of tube 51 by the force as it is, and acts perpendicularly to outer circumferential surface 51a of tube 51. Thus, the pressing force from conducting member 50 to each connection pad 33 is equally distributed to each connection pad 33. As a result, each conducting pattern 55 is uniformly in contact with each connection pad 33. Through the above step, connector assembly 1 in which conductors 23 are electrically connected to connection pads 33 through conducting patterns 55 is obtained.

The effects obtained by cable assembly 2 and connector assembly 1 of the embodiment described above will be described together with the problems of a comparative example.

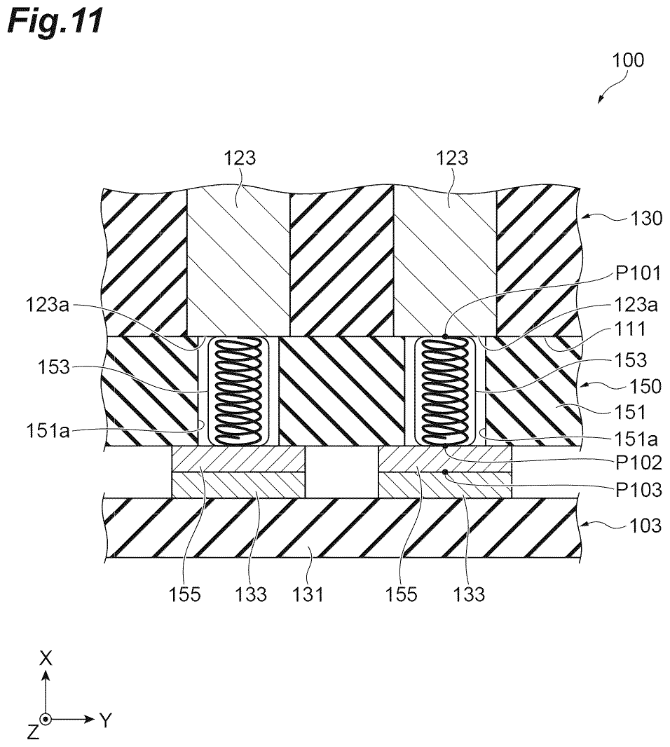

FIG. 11 is a cross-sectional view of a connector assembly 100 according to the comparative example. Connector assembly 100 includes a conducting member 150 between each conductor 123 of a connector 130 and each connection pad 155 of a connection board 103. Conducting member 150 is attached to a ferrule end face 111 and ensures the conducting between each conductor 123 exposed from ferrule end face 111 and each connection pad 155. Conducting member 150 includes a support plate 151, a plurality of elastic springs 153, and connection pads 155. Each of elastic springs 153 is accommodated in each of accommodation holes 151a formed in support plate 151, respectively. One end of each elastic spring 153 is in contact with each connection pad 155 arranged so as to close each accommodation hole 151a on one surface of support plate 151. The other end of each elastic spring 153 is in contact with each conductor 123 of connector 130. Each connection pad 155 is in contact with each connection pad 133 of connection board 103. As a result, each conductor 123 is electrically connected to each connection pad 133 through conducting member 150. Thus, a signal propagating through conductor 123 is provided from ferrule end face 111 of connector 130 to connection pad 133 of connection board 103 through elastic spring 153 and connection pad 155.

When conducting member 150 is interposed between an end surface 123a and connection pad 133, it may be difficult to reliably bring conducting member 150 into contact with end surface 123a depending on the degree of the unevenness of end surface 123a. Thus, it is conceivable to use conducting member 150 having elastic spring 153 having both conductivity and elasticity as in connector assembly 100.

However, when elastic spring 153 is used as in connector assembly 100, the inductance of elastic spring 153 itself formed of a coil is large. Further, in connector assembly 100, three connection points, that is, a connection point P101 between conductor 123 and elastic spring 153, a connection point P102 between elastic spring 153 and connection pad 155, and a connection point P103 between connection pad 155 and connection pad 133, exist between conductor 123 and connection pad 155. In this case, the attenuation of the signal is relatively large due to the contact resistance at each connection point. Thus, in connector assembly 100, it is difficult to reduce transmission loss when the signal is transmitted from conductor 123 to connection pad 133 through conducting member 150 while ensuring the conducting between conductor 123 and connection pad 133. Furthermore, in connector assembly 100, there is a concern that the pressing force applied from conductor 123 to elastic spring 153 varies for each elastic spring 153, and the transmission characteristics of the signal change.

On the other hand, cable assembly 2 of the embodiment includes conducting member 50 including tube 51 and conducting pattern 55 formed on outer circumferential surface 51a of tube 51. Thus, even when end surface 23a is formed with the unevenness, conducting pattern 55 can be more reliably brought into contact with end surface 23a by using the deformation of tube 51 when ferrule end face 11 is connected to connection board 3. Thus, it is possible to more reliably ensure the conducting between conductor 23 and conducting member 50. Further, conducting pattern 55 includes conductor contact portion P1 in contact with end surface 23a, pad contact portion P2 in contact with connection pad 33, and intermediate portion P3 connecting conductor contact portion P1 and pad contact portion P2. Thus, conductor 23 of flat cable 20 can be electrically connected to connection pad 33 of connection board 3 through conducting pattern 55.

Thus, in the embodiment, unlike connector assembly 100, the conducting between conductor 23 and connection pad 33 is ensured without using elastic spring 153, and thus it is possible to reduce the increase in the transmission loss due to the magnitude of the impedance of conducting member 50 itself. Furthermore, when the configuration is adopted in which the conducting between conductor 23 and connection pad 33 is secured only through conducting pattern 55, it is possible to reduce the occurrence of impedance mismatching between conductor 23 and connection pad 33, as compared to a case where a plurality of members such as elastic spring 153 and connection pad 155 are interposed between conductor 23 and connection pad 33. Further, when conducting pattern 55 is interposed between conductor 23 and connection pad 33, only two connection points, i.e., a connection point P11 between conductor 23 and conducting pattern 55 and a connection point P12 between conducting pattern 55 and connection pad 33, exist between conductor 23 and connection pad 33 (see FIG. 9). In this case, as compared with the case where three connection points P101, P102, and P103 exist as in connector assembly 100, it is possible to reduce the risk of occurrence of a non-contact portion or a portion having a large electrical resistance between members at each of connection points P11 and P12. Thus, it is possible to more reliably ensure the conducting between conductor 23 and connection pad 33. As a result, in the embodiment, it is possible to reduce the transmission loss of the signal propagating through conductor 23 while ensuring electrical connection between connection pad 33 of connection board 3 and conductor 23 of flat cable 20.

As in the embodiment, conducting member 50 may include a plurality of conducting patterns 55 formed on outer circumferential surface 51a of tube 51. The plurality of conducting patterns 55 may be in contact with end surfaces 23a of the plurality of conductors 23, respectively. In this case, as compared with a case where one conducting member 50 is provided for each of the plurality of conductors 23, it is possible to reduce the occurrence of variations in stress applied to each conductor 23 when ferrule end face 11 is connected to connection board 3. That is, the contact pressure of each conductor 23 is made uniform, and the contact pressure of only the specific conductor 23 is not increased. Thus, it is possible to reduce variations in transmission loss of conductors 23 due to the difference in contact pressure between conductors 23.

As in the embodiment, inert liquid L may be accommodated in tube 51. In this case, when conductors 23 are connected to connection board 3 through conducting member 50, even if the distances between conductors 23 and connection pads 33 of connection board 3 are slightly different from each other, the force of tube 51 pressing conductors 23 and connection pads 33 is uniform according to Pascal's law. Thus, it is possible to reduce variations in transmission loss of conductors 23 due to the difference in contact pressure between conductors 23.

As in the embodiment, the pair of lids 53 may be made of a material harder than tube 51. In this case, the elastic force of tube 51 acts in a direction in which each conducting pattern 55 is more reliably brought into contact with each conductor 23 or each connection pad 33. Thus, it is possible to more reliably ensure the conducting between flat cable 20 and conducting member 50.

As in the embodiment, each of the plurality of conducting patterns 55 may have an annular shape extending along outer circumferential surface 51a so as to be wrapped around central axis CL of tube 51. In this case, each conducting pattern 55 can be easily brought into contact with end surface 23a of each conductor 23.

As in the embodiment, conducting member 50 may include a plate-shaped frame body 57 into which tube 51 is fitted, and front surface 57a of frame body 57 may be attached to ferrule end face 11. In this case, tube 51 can be easily attached to ferrule end face 11 through the plate-shaped frame body 57.

As in the embodiment, ferrule side face 12 may be provided with engaging portion 12a that can engage with connection board 3. In this case, ferrule 10 and connection board 3 can be positioned by using engaging portion 12a. Thus, it is possible to more reliably bring conducting pattern 55 into contact with end surface 23a of conductor 23 when ferrule end face 11 is connected to connection board 3. Thus, it is possible to more reliably ensure the conducting between flat cable 20 and conducting member 50.

As in the embodiment, recess 11a of ferrule end face 11 may be configured to be able to accommodate at least a portion of tube 51. In this case, the contact area of conducting member 50 with ferrule 10 can be increased as compared with the case where ferrule end face 11 is a flat surface. Thus, conducting member 50 can be more reliably attached to ferrule 10 by using recess 11a.

As in the embodiment, each of end surfaces 23a of the plurality of conductors 23 may have a circular shape when viewed in the X-axis direction. In this case, each conducting pattern 55 can be easily brought into contact with end surface 23a of each conductor 23.

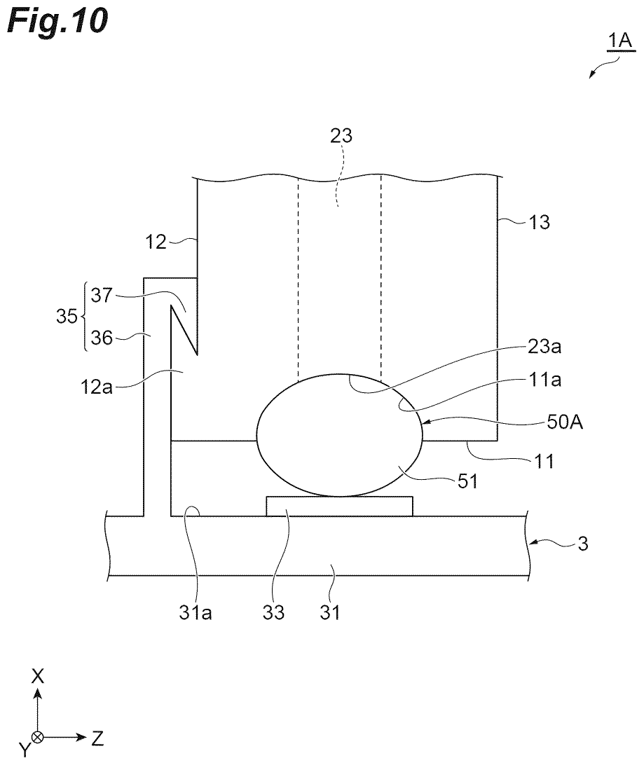

The present disclosure is not limited to the above-described embodiments, and various modifications are possible. FIG. 10 is a side view of a connector assembly 1A related to a modification. A conducting member 50A may not include frame body 57 as in connector assembly 1A. In this case, tube 51 is fixed to recess 11a of ferrule end face 11. The embodiment shown in FIG. 10 can also provide the same effect as the above-described embodiment.

In the above-described embodiment, the connection board is exemplified as the “connection object”. However, the “connection object” is not limited to the connection board, and may be another connection portion component such as a receptacle as long as the connection object can be electrically connected to the “cable assembly”. In the above-described embodiment, the case where the “conducting member” is attached to the ferrule has been exemplified. However, the “conducting member” may be attached to the “connection object”. In the above-described embodiment, the cable assembly includes one conducting member. However, the “cable assembly” may include a plurality of “conducting members”. In this case, the plurality of “conducting members” may be disposed one by one between the end surface of each conductor of the flat cable and each connection portion of the connection object. In this case, each of the plurality of “conducting members” may include, for example, a rubber ball as an “elastic body”, and a conducting pattern may be formed on an outer surface of the rubber ball.

What is claimed is:

1. A cable assembly comprising:
a flat cable including a plurality of conductors arranged side by side and a covering that covers the plurality of conductors, each of the plurality of conductors having an end exposed from the covering;
a ferrule including a ferrule end face and a plurality of insertion holes extending from the ferrule end face and arranged side by side, the ferrule holding the flat cable with the end of each of the plurality of conductors inserted in a corresponding one of the plurality of insertion holes; and
at least one conducting member to be attached to the ferrule end face and electrically connected to end surfaces of the plurality of conductors, the end surfaces of the plurality of conductors being exposed from the ferrule end face, wherein
the at least one conducting member includes
an elastic body elastically deformable in response to a pressing force applied to the ferrule end face, and
a conducting pattern formed on an outer surface of the elastic body, and
the conducting pattern includes
a first portion disposed on the outer surface and to be brought into contact with the end surface of a conductor included in the plurality of conductors,
a second portion disposed on the outer surface at a position away from the first portion, and
a third portion extending on the outer surface to connect the first portion and the second portion to each other.

2. The cable assembly according to claim 1, wherein
the at least one conducting member comprises a single conducting member,
the single conducting member includes the elastic body and a plurality of the conducting patterns, the elastic body comprising a tube extending in an arrangement direction in which the plurality of conductors are arranged, the plurality of conducting patterns being formed on an outer surface of the tube, and
the plurality of conducting patterns are arranged on the outer surface at positions, each corresponding to one of the plurality of conductors, spaced at intervals in the arrangement direction, each of the plurality of conducting patterns being in contact with a corresponding one of the end surfaces of the plurality of conductors.

3. The cable assembly according to claim 2, wherein
the tube has a cylindrical shape with two ends thereof closed, and
an inert liquid is accommodated inside the tube.

4. The cable assembly according to claim 3, wherein
the tube includes a pair of lids placed at the two ends to close the two ends, and
the pair of lids are made of a harder material than the tube.

5. The cable assembly according to claim 2, wherein
each of the plurality of conducting patterns has an annular shape extending along the outer surface so as to be wrapped around a central axis of the tube.

6. The cable assembly according to claim 2, wherein
the single conducting member further includes a plate-shaped frame body into which the tube is to be fitted,
the frame body includes
a front surface having therein a first opening from which the first portions of the plurality of conducting patterns are exposed, and
a rear surface having therein a second opening from which the second portions of the plurality of conducting patterns are exposed, and
the front surface is attached to the ferrule end face.

7. The cable assembly according to claim 1, wherein
the ferrule further includes a ferrule side face extending from the ferrule end face in an extending direction in which the plurality of conductors extend, and
the ferrule side face has an engaging portion engageable with a connection object.

8. The cable assembly according to claim 1, wherein
the ferrule end face includes a recess, the recess being recessed from ferrule end face toward a side opposite to the at least one conducting member, and
the recess is configured such that at least a portion of the elastic body is receivable in the recess.

9. The cable assembly according to claim 1, wherein
each of the end surfaces of the plurality of conductors has a circular shape when viewed along an extending direction in which the plurality of conductors extend.

10. A connector assembly comprising:
a flat cable including a plurality of conductors arranged side by side and a covering that covers the plurality of conductors, each of the plurality of conductors having an end exposed from the covering;
a ferrule including a ferrule end face and a plurality of insertion holes extending from the ferrule end face and arranged side by side, the ferrule holding the flat cable with the end of each of the plurality of conductors inserted in a corresponding one of the plurality of insertion holes;
a connection object including a plurality of connection portions, each facing a corresponding one of end surfaces of the plurality of conductors, the connection object facing the ferrule end face; and
at least one conducting member disposed between the ferrule end face and the connection object and configured to electrically connect each of the end surfaces of the plurality of conductors to a corresponding one of the plurality of connection portions, the end surfaces of the plurality of conductors being exposed from the ferrule end face, wherein
the at least one conducting member includes
an elastic body elastically deformable in response to a pressing force applied to the ferrule end face, and
a conducting pattern formed on an outer surface of the elastic body, and
the conducting pattern includes
a first portion disposed on the outer surface and to be brought into contact with the end surface of a conductor included in the plurality of conductors,
a second portion disposed on the outer surface at a position away from the first portion, the second portion being brought into contact with a connection portion included in the plurality of connection portions, and
a third portion extending on the outer surface to connect the first portion and the second portion to each other.
